(19) United States
(12) Patent Application Publication
(10) Pub. No.: US 2009/0230418 A1
(43) Pub. Date: Sep. 17, 2009

(54) LIGHT EMITTING DIODE PACKAGE AND METHOD OF MANUFACTURING THE SAME

(75) Inventor: Hyung Kun Kim, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/266,640

(22) Filed: Nov. 7, 2008

(30) Foreign Application Priority Data
Mar. 12, 2008 (KR) 10-2008-0022859

(51) Int. Cl. H01L 33/00

(52) U.S. Cl. 257/98; 438/27; 257/E33.061

(57) ABSTRACT

There is provided a light emitting diode package and a method of manufacturing the same in which a light emitting diode chip is separated from phosphors, and a phosphor area is variable in shape to improve thermal balance and luminous efficiency. A light emitting diode package according to an aspect of the invention may include: a package body; at least one LED chip mounted in an area of the package body and emitting excitation light; and a lens unit separated from the LED chip by a distance and mounted on an upper surface of the package body, wherein the lens unit may include a phosphor area located at one side of a lower part thereof, absorbing the excitation light of the LED chip, and generating wavelength-converted light. According to the invention, since the lens unit corresponding to the LED chip is separated from the LED chip by the predetermined distance, there can be provided the light emitting diode package having improved luminous efficiency and reliability that the phosphors are not thermally deformed by heat generated from the LED chip.

### CROSS-REFERENCE TO RELATED APPLICATIONS

This application claims the priority of Korean Patent Application No. 2008-0022859 filed on Mar. 12, 2008, in the Korean Intellectual Property Office, the disclosure of which is incorporated herein by reference.

### BACKGROUND OF THE INVENTION

1. Field of the Invention

The present invention relates to light emitting diode packages and a method of manufacturing the same, and more particularly, to a light emitting diode package and a method of manufacturing the same in which a light emitting diode chip is separated from phosphors, and a phosphor area is variable in shape to improve thermal balance and luminous efficiency.

2. Description of the Related Art

White light emitting diodes (hereinafter, simply referred to as an “LED”) are semiconductor device packages that display white by fabricating light sources using compound semiconductor materials, such as GaAs, AlGaAs, GaN, InGaN, and AlGaInP.

In general, factors used to determine characteristics of the LED package may include color, luminance, and a range of luminous intensity. The characteristics of the LED package are primarily determined by compound semiconductor materials of an LED used in the LED package. Secondarily, the characteristics of the LED package are affected by a package structure for mounting an LED chip. In order to obtain high luminance and luminance distribution according to the user's needs, the above-described primary factor according to the material development is limited. Therefore, the package structure has attracted much attention.

As information and communication devices have been reduced in size, thickness, and weight, components of the information and communication devices, for example, resistors, condensers, and noise filters, have been significantly reduced in size. The components are directly mounted onto the surface of a printed circuit board (PCB), and any devices so made are called surface mount devices (SMDs).

LED packages that are used as display devices have been correspondingly developed into SMD LED packages. This SMD LED package can replace the existing lighting lamp and is used as a character indicator, an image indicator, or a lighting indicator, which displays various colors.

As such, as the LED package is used in a wide range of applications, the required amount of luminance of lamps used daily or emergency signal lamps is increasing steadily. Recently, a high-power white LED package has come into widespread use.

FIG. 1 is an exemplary view illustrating a white LED package according to the related art.

As shown in FIG. 1, in an LED package according to the related art, a reflection hole is formed in a PCB 20 so that an LED 21 is mounted in the reflection hole, a reflective coating layer 20-1 formed of Ag is formed in the reflection hole, and then the reflective coating layer 20-1 is connected to package electrodes 22 and 23 to apply power to the LED 21.

When the reflective coating layer 20-1 is formed in the PCB 20, the LED 21 is located at a lower part of the reflection hole, and a P electrode and an N electrode of the LED 21 are electrically connected to the reflective coating layer 20-1.

When the LED 21 is mounted in the reflection hole, a cathode electrode 22 and an anode electrode 23 are formed at both sides of the reflective coating layer 20-1 by a solder bonding method. Then, a phosphor molding unit 24 that includes a red phosphor, a green phosphor, and a blue phosphor is injected into the reflection hole of the PCB 20 mounted with the LED 21 so as to inhibit oxidization of a wire 21-2 and convert light generated from the LED 21 into white light.

The LED package then converts light generated from the LED 21 into white light in the phosphor molding unit 24, and emits the white light to the outside by a mold lens 25.

However, according to the related art, in the white LED package, heat generated from the LED 21 is directly transferred to the phosphor molding unit 24 to cause thermal deformation of the phosphors in the phosphor molding unit 21. As a result, light conversion efficiency with which light generated from the LED 21 is converted into light having a different wavelength is reduced.

Further, since it is impossible to change the distance between the LED 21 and the phosphor molding unit 24 to obtain a desired distance, it is difficult to improve luminous efficiency of the LED package.

### SUMMARY OF THE INVENTION

An aspect of the present invention provides a light emitting diode package and a method of manufacturing the same in which a light emitting diode chip is separated from phosphors, and a phosphor area is variable in shape.

According to an aspect of the present invention, there is provided a light emitting diode package including: a package body; at least one LED chip mounted in an area of the package body and emitting excitation light; and a lens unit separated from the LED chip by a distance and mounted on an upper surface of the package body, wherein the lens unit may include a phosphor area located at one side of a lower part thereof, absorbing the excitation light of the LED chip, and generating wavelength-converted light.

The light emitting diode package may further include a reflective pattern formed of a metallic material, located on the upper surface of the package body, and connected to edges of the lens unit.

The package body may be a printed circuit board.

The package body may include a via for making an electrical connection of the LED chip to the outside.

The phosphor area may have a thickness increasing towards the center from edges or a uniform thickness at a lower surface of the lens unit.

The phosphor area may have a radial shape and be provided at one side of a lower part of the lens unit.

The phosphor area may include: a first phosphor area including a first phosphor and located at one side of the lower part of the lens unit; and a second phosphor area including a second phosphor and overlapping the first phosphor area.

According to another aspect of the present invention, there is provided a method of manufacturing a light emitting diode package, the method including: providing a lens unit formed of a transparent lens material; forming a recessed part at one portion of a plane of the lens unit and forming a phosphor area by filling and curing liquid resin including a phosphor; and mounting the lens unit on an upper surface of the package body so that the phosphor area of the lens unit is separated from at least one LED chip mounted in an area of the package body.

The recessed part may be formed by dry etching or wet etching one portion of a plane of the lens unit.

The package body may include a reflective pattern formed of a metallic material, located on the upper surface of the package body, and connected to edges of the lens unit.

The package body may be a printed circuit board.

The package body may include a via for making an electrical connection of the LED chip to the outside.

In the mounting the lens unit on an upper surface of the package body, the lens unit may be mounted on the upper surface of the package body through paste applied to the edges of a lower surface thereof.

In the forming a phosphor area, the phosphor area may have a thickness increasing towards the center from edges or a uniform thickness at the lower surface of the lens unit.

In the forming a phosphor area, the phosphor area may be located at a lower part of the lens unit and have a radial shape to diffuse wavelength-converted light.

In the forming a phosphor area, the phosphor area may include: a first phosphor area including a first phosphor and located at one side of the lower part of the lens unit; and a second phosphor area including a second phosphor and overlapping the first phosphor area.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is an exemplary view illustrating an LED package according to the related art;

FIG. 2 is a cross-sectional view illustrating a light emitting diode package according to an exemplary embodiment of the invention;

FIGS. 3A to 3C are cross-sectional views illustrating a process of manufacturing the light emitting diode package according to the embodiment of FIG. 2;

FIG. 4 is a cross-sectional view illustrating a light emitting diode package according to another embodiment of the invention;

FIG. 5 is a cross-sectional view illustrating a light emitting diode package according to still another embodiment of the invention; and

FIG. 6 is a cross-sectional view illustrating a light emitting diode package according to yet another embodiment of the invention.

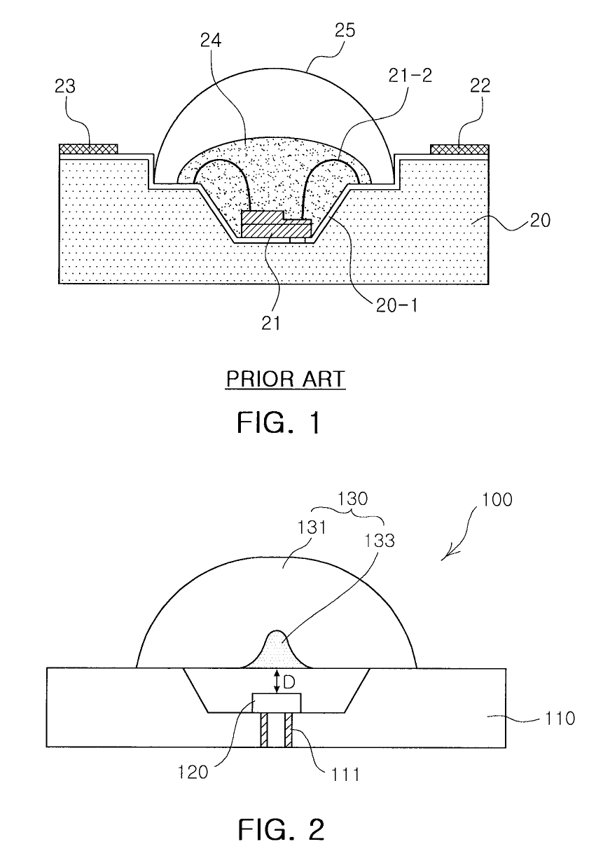

### DETAILED DESCRIPTION OF THE PREFERRED EMBODIMENT

Exemplary embodiments of the present invention will now be described in detail with reference to the accompanying drawings. In the description of the invention, if it is determined that a detailed description of commonly-used technologies or structures related to a light emitting diode package of the invention may unnecessarily obscure the subject matter of the invention, the detailed description will be omitted.

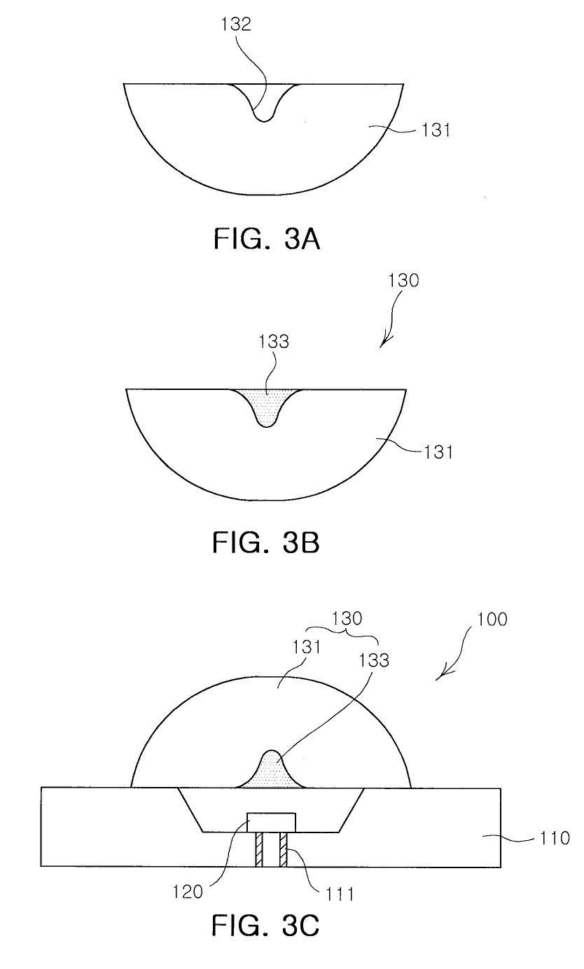

FIG. 2 is a cross-sectional view illustrating a light emitting diode (LED) package according to an exemplary embodiment of the invention. FIGS. 3A to 3C are cross-sectional views illustrating a process of manufacturing the LED package according to the exemplary embodiment of the invention.

As shown in FIG. 2, an LED package 100 according to this embodiment includes a package body 110, such as a printed circuit board, at least one LED chip 120, and a lens unit 130. The LED chip 120 is mounted in the area of the package body 110, and emits excitation light. The lens unit 130 includes a hemispheric lens area 131 and a phosphor area 133. The hemispheric lens area 131 is separated from the LED chip 120, and mounted on an upper surface of the package body 110. The phosphor area 133 is located at a portion of a lower surface of the lens area 131, and absorbs the excitation light of the LED chip 120 to generate wavelength-converted light. Here, a reflective layer (not shown) is provided along a bottom surface of the area of the package body 110 in which the at least one LED chip 120 is mounted. The reflective layer reflects excitation light and wavelength-converted light to emit the excitation light and the wavelength-converted light to the outside.

Further, in order to make an electrical connection of the LED chip 120 to the outside, a via 111 may be provided under the area of the package body 110 in which the at least one chip 120 is selectively mounted.

The lens unit 130 is placed on the upper surface of the package body 110 and separated by the distance D from the LED chip 120 corresponding to the lens unit 130. Here, the lens unit 130 includes the hemispheric lens area 131 and the phosphor area 133. Examples of phosphors of the phosphor area 133 may include i) rare-earth oxide, sulfide, and nitride phosphors or ii) semiconductor nitride, sulfide, oxide, and phosphide phosphors.

Here, the phosphors of the phosphor area 133 may be formed into a predetermined shape on the lower surface of the lens unit 130. For example, as shown in FIG. 2, the phosphors have a thickness increasing towards the center from both edges. Light with high intensity incident from the center of the LED chip 120 and light incident from the edges of the LED chip 120 respond to the phosphor area 133, thereby emitting uniform wavelength-converted light. Alternatively, the phosphor area 133 may correspond to the LED chip 120, be located at the lower surface of the lens unit 130, and overlap the area of the package body 110.

As described above, in the LED package 100 according to this embodiment, the lens unit 130 is mounted while being separated by the distance D from the LED chip 120 corresponding to the lens unit 130. Since heat generated from the LED chip 120 is not directly transferred to the phosphor area 133, the phosphors of the phosphor area 133 are not thermally deformed, thereby improving luminous efficiency and reliability of the LED package 100.

Further, the lens unit 130 may be mounted on the package body 110 by changing the distance D between the LED chip 120 and the phosphor area 133. The lens unit 130 may be replaced with another lens unit having a phosphor area with a different shape from that of the phosphor area 133.

Hereinafter, a method of manufacturing the LED package 100 according to the exemplary embodiment of the invention will be described with reference to FIGS. 3A to 3C.

As shown in FIG. 3A, in order to manufacture the LED package 100 according to the embodiment of the invention, a recessed part 132 is formed in the center of a plane of the hemispheric lens area 131 that is formed of a transparent lens material.

In order to form the recessed part 132 in the center of the plane of the lens area 131, a photo resist pattern (not shown) is formed on the plane of the lens area 131, and then etched. Dry etching or wet etching may be selectively performed according to the shape of the recessed part 132. The recessed part 132 may be formed by using a method of injecting a molten lens material into a mold having a shape corresponding to the shape of the lens area 131 and the groove part 132, and hardening the injected lens material.

Once the recessed part 132 is formed at the center of the plane of the lens area 131, as shown in FIG. 3B, liquid resin containing phosphors is injected into the recessed part 132 and then cured to form the phosphor area 133.

Specifically, examples of the phosphors contained in the liquid resin to form the phosphor area 133 may include i) rare-earth oxide, sulfide, and nitride phosphors or ii) semiconductor nitride, sulfide, oxide, and phosphide phosphors. The phosphors may be filled and cured in the recessed part 132 by a method such as screen printing.

Then, as shown in FIG. 3C, the lens unit 130 including the phosphor area 133 is mounted on the upper surface of the area of the package body 110 mounted with at least one LED chip 120.

At this time, the lens unit 130 may be mounted on the upper surface of the package body 110 by using paste applied to the edges, and the area in the package body 110 mounted with the LED chip 120 may be formed to adjust the distance D between the phosphor area 133 and the LED chip 120. The phosphor area 133 may be formed at the inside of the lens unit 130 in order to increase the distance D between the phosphor area 133 and the LED chip 120.

The problem that it is impossible to change the distance between the LED 21 and the phosphor molding unit 24 to obtain a desired distance can be easily solved since the phosphor area 133 is directly formed and mounted in the lens unit 130 in the LED package 100 according to this embodiment. Furthermore, since it is possible to easily remove the lens unit 130, the lens unit 130 can be exchanged into a lens unit having a phosphor area with a different shape from that of the phosphor area 133 to meet the user's needs.

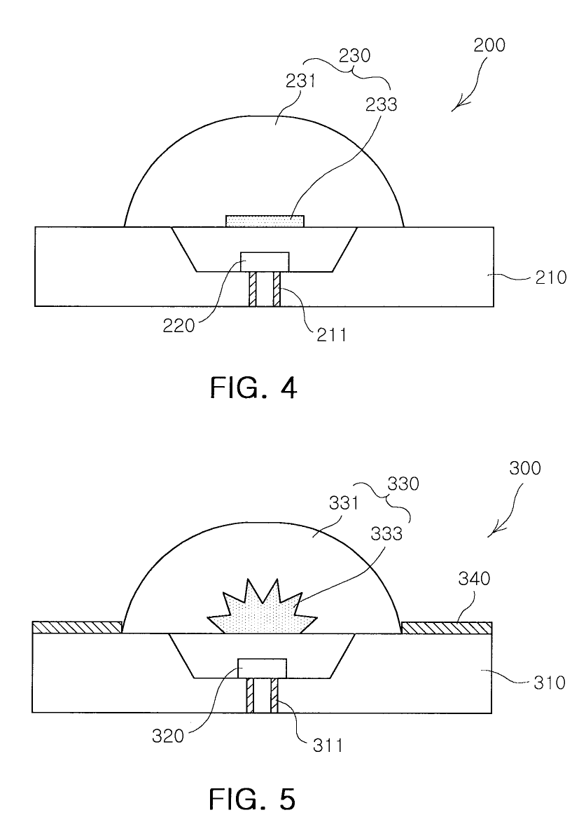

As described above, the lens unit 130 is easily removed and exchanged into a lens unit having a phosphor area with a different shape from that of the phosphor area 133. As shown in FIG. 4, in an LED package 200 according to another exemplary embodiment of the invention, instead of the lens unit 130, a lens unit 230 having a phosphor area 233 with a uniform thickness at a bottom surface thereof may be mounted on an upper surface of a package body 210.

As shown in FIG. 5, in an LED package 300 according to still another exemplary embodiment of the invention, a phosphor area 333 having a radial shape is formed at a lower part of the lens unit 330, and converts a wavelength of light generated from an LED chip 320 to diffuse light to the outside through a lens area 331. Luminous efficiency of the LED package 300 can be improved by diffusing the wavelength-converted light by using the phosphor area 333 having the radial shape.

Optionally, the LED package 300 according to this embodiment may include a reflective pattern 340. The reflective pattern 340 is provided at the upper surface of a package body 310 and serves as a mounting frame formed of a metallic material for the lens unit 330. The reflective pattern 340 facilitates mounting the lens unit 330 to thereby improve the luminous efficiency of the LED package 300.

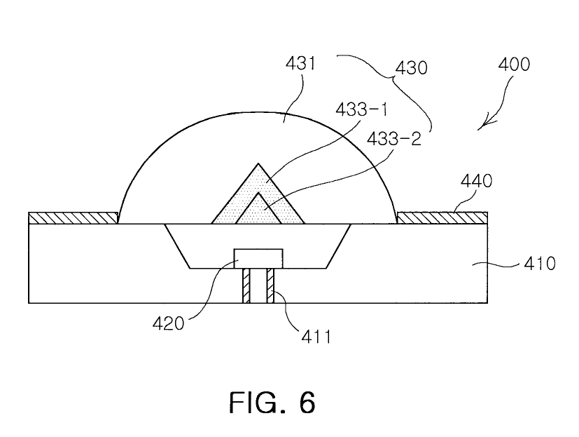

As shown in FIG. 6, an LED package 400 according to yet another embodiment of the invention includes a phosphor area having a first phosphor area 433-1 and a second phosphor area 433-2 that are located at a lower part of a lens unit 430 and overlap each other. The phosphor area converts a wavelength of light generated from the LED chip 420 and emits the wavelength-converted light to the outside through a lens area 431. The first phosphor area 433-1 and the second phosphor area 433-2 constitute the phosphor area. In particular, for white light emission, a phosphor for converted red light may be included in the first phosphor area 433-1, and phosphors for converted blue light and converted green light may be included in the second phosphor area 433-2.

Here, in order to form the first phosphor area 433-1 and the second phosphor area 433-2, that is, first dry etching is performed on the lens area 431 to form a first recessed part for the first phosphor area 433-1, and second wet etching is performed on the first phosphor area 433-1 filled and cured in the first recessed part to form a second recessed part for the second phosphor area 433-2. After the second etching is completed, the second phosphor area 433-2 may be formed.

Like the LED package 300 according to still another embodiment of the invention, the LED package 400 according to this embodiment of the invention includes a reflective pattern 440 that is located on the upper surface of a package body 410 and serves as a mounting frame formed of a metallic material for the lens unit 430. The reflective pattern 440 facilitates mounting the lens unit 430 and improves the luminous efficiency of the LED package 400.

As described above, the lens unit having the phosphor area variable in shape is separated from the LED chip by the predetermined distance, the lens unit can be mounted or demounted, and the thickness and shape of the phosphor area are variously controlled, such that thermal deformation of the phosphors can be prevented, and the luminous efficiency of the LED package can be improved.

As set forth above, according to the exemplary embodiments of the invention, since the lens unit corresponding to the LED chip is separated from the LED chip by the predetermined D, heat generated from the LED chip is not directly transferred to the phosphor area, thereby preventing thermal deformation of the phosphors and improving luminous efficiency and reliability of the LED package.

Further, according to the embodiments of the invention, an LED package is provided in which a lens unit can be mounted on a package body by controlling a distance D between the LED chip and the phosphor area, and the lens unit can be replaced with a lens unit having a phosphor area variable in shape.

While the present invention has been shown and described in connection with the exemplary embodiments, it will be apparent to those skilled in the art that modifications and variations can be made without departing from the spirit and scope of the invention as defined by the appended claims.

What is claimed is:

1. A light emitting diode package comprising:
a package body;
at least one LED chip mounted in an area of the package body and emitting excitation light; and
a lens unit separated from the LED chip by a distance and mounted on an upper surface of the package body,
wherein the lens unit comprises a phosphor area located at one side of a lower part thereof, absorbing the excitation light of the LED chip, and generating wavelength-converted light.

2. The light emitting diode package of claim 1, further comprising a reflective pattern formed of a metallic material, located on the upper surface of the package body, and connected to edges of the lens unit.

3. The light emitting diode package of claim 1, wherein the package body is a printed circuit board.

4. The light emitting diode package of claim 1, wherein the package body includes a via for making an electrical connection of the LED chip to the outside.

5. The light emitting diode package of claim 1, wherein the phosphor area has a thickness increasing towards the center from edges or a uniform thickness at a lower surface of the lens unit.

6. The light emitting diode package of claim 1, wherein the phosphor area has a radial shape and is provided at one side of a lower part of the lens unit.

7. The light emitting diode package of claim 1, wherein the phosphor area comprises:
a first phosphor area including a first phosphor and located at one side of the lower part of the lens unit; and
a second phosphor area including a second phosphor and overlapping the first phosphor area.

8. A method of manufacturing a light emitting diode package, the method comprising:
providing a lens unit formed of a transparent lens material;
forming a recessed part at one portion of a plane of the lens unit and forming a phosphor area by filling and curing liquid resin including a phosphor; and
mounting the lens unit on an upper surface of the package body so that the phosphor area of the lens unit is separated from at least one LED chip mounted in an area of the package body.

9. The method of claim 8, wherein the recessed part is formed by dry etching or wet etching one portion of a plane of the lens unit.

10. The method of claim 8, wherein the package body comprises a reflective pattern formed of a metallic material, located on the upper surface of the package body, and connected to edges of the lens unit.

11. The method of claim 8, wherein the package body is a printed circuit board.

12. The method of claim 8, wherein the package body comprises a via for making an electrical connection of the LED chip to the outside.

13. The method of claim 8, wherein in the mounting the lens unit on an upper surface of the package body, the lens unit is mounted on the upper surface of the package body through paste applied to the edges of a lower surface thereof.

14. The method of claim 8, wherein in the forming a phosphor area, the phosphor area has a thickness increasing towards the center from edges or a uniform thickness at the lower surface of the lens unit.

15. The method of claim 8, wherein in the forming a phosphor area, the phosphor area is located at a lower part of the lens unit and has a radial shape to diffuse wavelength-converted light.

16. The method of claim 8, wherein in the forming a phosphor area, the phosphor area comprises:
a first phosphor area including a first phosphor and located at one side of the lower part of the lens unit; and
a second phosphor area including a second phosphor and overlapping the first phosphor area.
